(19) United States
(12) Patent Application Publication
(10) Pub. No.: US 2007/0090541 A1
(43) Pub. Date: Apr. 26, 2007

(54) BONDING PAD AND DISPLAY PANEL

(76) Inventor: Chih-Chung Tu, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/163,512

(22) Filed: Oct. 21, 2005

(51) Int. Cl. H01L 23/48

(52) U.S. Cl. 257/786

(57) ABSTRACT

A bonding pad including an insulating layer, a pad metal layer, at least a patterned layer, a passivation layer and a conductive layer is described. The insulating layer is disposed on a substrate. The pad metal layer is disposed over the insulating layer. The at least a patterned layer is disposed in at least one of the positions of between the insulating layer and the substrate and between the insulating layer and the pad metal layer so that the in insulating layer or the pad metal layer has an uneven surface. The passivation layer is disposed over the pad metal layer. The conductive layer is disposed over the passivation layer, and the conductive layer is electrically connected to the pad metal layer.

### BACKGROUND OF THE INVENTION

1. Field of the Invention

The present invention generally relates to a bonding pad and a display panel. More particularly, the present invention relates to a bonding pad capable of improving the adhesion of the pad metal layer, and a display panel using the same.

2. Description of Related Art

As video techniques are developed, display devices are more important and valued. Usually, a display device has a display panel for displaying images, and the display panel is driven by driving chips. In other words, images are displayed on the display panel through driving signals provided by the driving chips. In order to electrically connect the driving chips and the display panel, a package structure is usually formed therebetween.

In a large size display panel process, tape carrier package (TCP) structures are used to electrically connect the driving chips and the display panel. However, in recent years, new driving chips have high input/output pin number and fine pitch, and the display panel having flexible property is required. Hence, chip on glass (COG) package structures and chip on film package (COF) structures are developed and applied to large size display panels.

FIG. 1A is a top view showing a conventional display panel. As shown in FIG. 1A, the display panel 100 includes a display region 110 and a non-display region 120. Scan lines 112, data lines 114 and pixel units 116 are disposed in the display region 110, and the scan lines 112 and the data lines 114 are electrically connected to the pixel units 116. Each of the scan lines 112 and each of the data lines 114 extending to the non-display region 120 respectively have a bonding pad 130. Driving chips (not shown) are bonded on the bonding pads 130 and are electrically connected to the bonding pads 130 so as to drive the display panel 100.

FIG. 1B is a diagram showing the bonding pads of FIG. 1A. FIG. 1C is a cross-section view along the A-A′ line of FIG. 1B. Please refer to FIG. 1B and FIG. 1C, the bonding pad 130 has a reduced width d because of high input/out pin number and fine pitch of the driving chip. FIG. 1C is a cross-section view showing one of the boning pads 130 of FIG. 1B. The boning pad 130 includes an insulating layer 134, a pad metal layer 136, a passivation layer 136 and a conductive layer 139. The insulating layer 134 is disposed on a substrate 132. The pad metal layer 136 is disposed on the insulating layer 134. The passivation layer 138 is disposed on the pad metal layer 136. The conductive layer 139 is disposed on the passivation layer 138, and the conductive layer 139 is electrically connected to the pad metal layer 136. In details, the conductive layer 139 is electrically connected to the pad metal layer 136 through the contact openings 150 as shown in FIG. 1B.

As shown in FIG. 1B and FIG. 1C, because the bonding pad 130 has a reduced width d, the contact area between layers of the bonding pad 130 is reduced. Therefore, the adhesion between the layers of the bonding pad 130 is lowered. In particular, the adhesion between the pad metal layer 136 and the insulating layer 134 is deteriorated as the width d is reduced. The pad metal layer 136 may easily peel off the insulating layer 134 when repairing the driving chip. As a result, the driving chip can not well electrically connected to the bonding pads 130, and thus the displaying quality is worsen and the display panel process yield is also deteriorated.

### SUMMARY OF THE INVENTION

Accordingly, the present invention is directed to a bonding pad capable of improving the adhesion between layers of the bonding pad. In particular, the adhesion between the pad metal layer and the insulating layer can be improved so as to improve the bonding pad process yield.

The present invention is directed to a display panel having the bonding pad of the present invention therein so as to improve the display panel process yield.

In the present invention, a bonding pad comprising an insulating layer, a pad metal layer, at least a patterned layer, a passivation layer and a conductive layer is provided. The insulating layer is disposed on a substrate. The pad metal layer is disposed over the insulating layer. The at least a patterned layer is disposed in at least one of the positions of between the insulating layer and the substrate and between the insulating layer and the pad metal layer so that the insulating layer or the pad metal layer has an uneven surface. The passivation layer is disposed over the pad metal layer. The conductive layer is disposed over the passivation layer and electrically connected to the pad metal layer.

A display panel having a display region and a non-display region is also provided. The display panel comprises a plurality of pixel units, a plurality of data lines, a plurality of scan lines, a plurality of scan line pads and a plurality of data line pads. The pixel units are disposed in the display region. The data lines and the scan lines are disposed in the display region and electrically connected to the pixel units. The scan line pads are disposed in the non-display region and electrically connected to the scan lines. The data line pads are disposed in the non-display region and electrically connected to the data lines. Each of the data line pad comprises an insulating layer, a pad metal layer, at least a patterned layer, a passivation layer and a conductive layer is provided. The insulating layer is disposed on a substrate. The pad metal layer is disposed over the insulating layer. The at least a patterned layer is disposed in at least one of the positions of between the insulating layer and the substrate and between the insulating layer and the pad metal layer so that the insulating layer or the pad metal layer has an uneven surface. The passivation layer is disposed over the pad metal layer. The conductive layer is disposed over the passivation layer and electrically connected to the pad metal layer.

According to an embodiment of the present invention, the at least a patterned layer is a metal layer and is disposed between the insulating layer and the substrate.

According to an embodiment of the present invention, the at least a patterned layer is an amorphous layer or a polysilicon layer and is disposed between the insulating layer and the pad metal layer.

According to an embodiment of the present invention, the at least a patterned layer comprises a first patterned layer between the insulating layer and the substrate and a second patterned layer between the insulating layer and the pad metal layer. The first patterned layer between the insulating layer and the substrate is a metal layer and the second patterned layer between the insulating layer and the pad metal layer is an amorphous layer or a polysilicon layer.

According to an embodiment of the present invention, the first patterned layer between the insulating layer and the substrate has a pattern the same to or different from that of the second patterned layer between the insulating layer and the pad metal layer.

According to an embodiment of the present invention, the pattern of the first patterned layer between the insulating layer and the substrate and the pattern of the second patterned layer between the insulating layer and the pad metal layer are aligned or not aligned to each other.

According to an embodiment of the present invention, the patterned layer has at least a pattern selected from a circular pattern, a square pattern, a polygon pattern and a combination thereof.

According to an embodiment of the present invention, the conductive layer comprises a metal oxide.

The bonding pad of the present invention has at least a patterned layer disposed between the insulating layer and the substrate and/or between the insulating layer and the pad metal layer so that the insulating layer or the pad metal layer has an uneven surface. As a result, the adhesion between layers of the bonding pad can be improved. In particular, the adhesion between the pad metal layer and the insulating layer can be improved, and thus the pad metal layer does not peel off the insulating layer. If the bonding pad of the present invention is applied to a display panel, the display panel process yield can also be improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view showing a conventional display panel.

FIG. 1B is a diagram showing the bonding pads of FIG. 1A.

FIG. 1C is a cross-section view along the A-A′ line of FIG. 1B.

FIG. 2 is a top view showing boning pads according to an embodiment of the present invention.

FIG. 2A is a cross-section view along B-B′ line of FIG. 2.

FIGS. 3A˜3C are cross-section views showing other three boning pads according to embodiments of the present invention.

FIG. 4 is a top view showing a display panel according to an embodiment of the present invention.

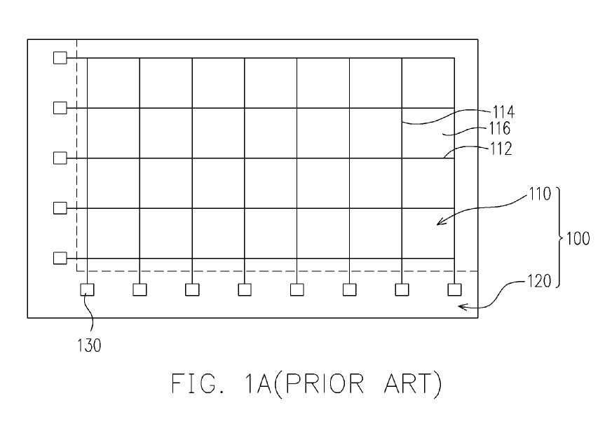

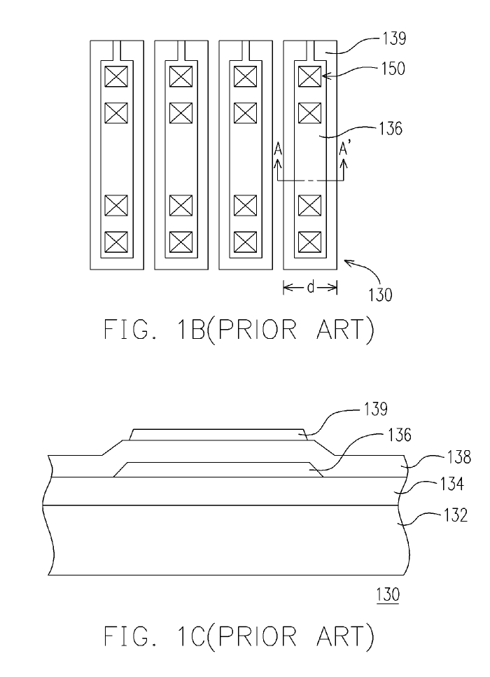

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

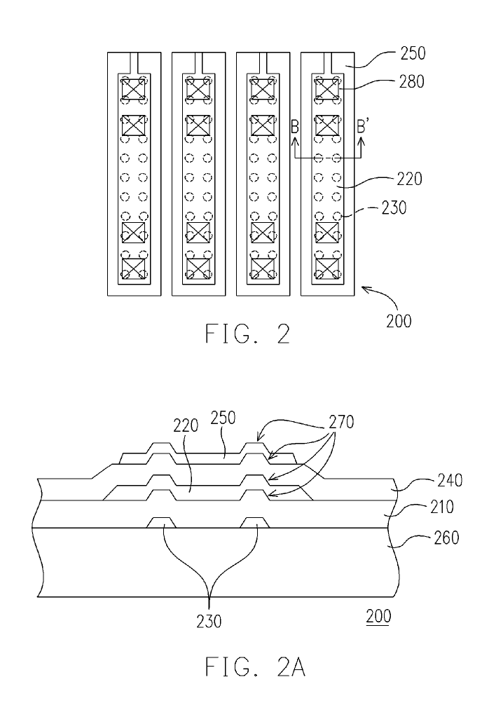

FIG. 2 is a top view showing boning pads according to an embodiment of the present invention. FIG. 2A is a cross-section view along the B-B′ line of FIG. 2. Please refer to FIG. 2 and FIG. 2A, the bonding pad 200 comprises an insulating layer 210, a pad metal layer 220, at least a patterned layer 230, a passivation layer 240 and a conductive layer 250. The insulating layer 210 is disposed over a substrate 260. The pad metal layer 220 is disposed over the insulating layer 210. The patterned layer 230 is disposed between the insulating layer 210 and the substrate 260 so that the insulating layer 210 has an uneven surface 270. The passivation layer 240 is disposed over the pad metal layer 220. The conductive layer 250 is disposed over the passivation layer 240 and is electrically connected to the pad metal layer 220. In details, the conductive layer 250 is electrically connected to the pad metal layer 220 through the contact openings 280 as shown in FIG. 2. In an embodiment of the present invention, the conductive layer 250 is a metal oxide, such as indium tin oxide (ITO) or indium zinc oxide (IZO).

Please refer to FIG. 2A, the patterned layer 230 is a metal layer, and the patterned layer 230 is disposed between the insulating layer 210 and the substrate 260. The insulating layer 210 has an uneven surface 270 corresponding to the patterned layer 230, and thus the surface roughness of the insulating layer 210 is increased. Hence, the pad metal layer 220 can be well adhered to the insulating layer 210 and does not peel off the insulating layer 210. Similarly, the pad metal layer 220, the passivation layer 240 and the conductive layer 250 may respectively have an uneven surface 270 because of the patterned layer 230 formation. Thus, the adhesion between layers of the bonding pad can be improved.

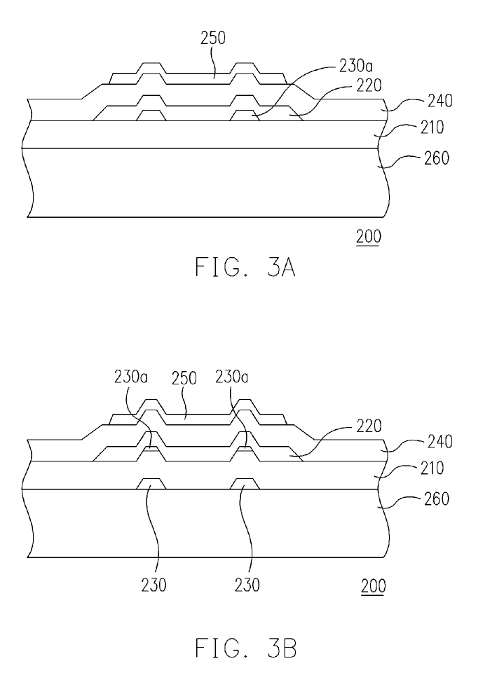

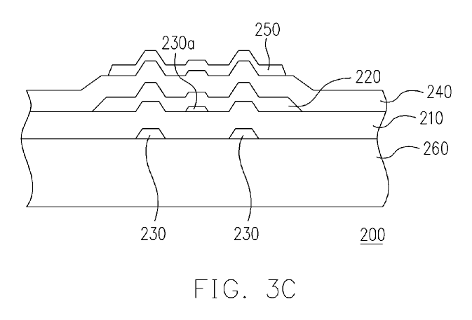

FIGS. 3A˜3C are cross-section views showing other three boning pads according to embodiments of the present invention. As shown in FIG. 3A, according to another embodiment, the patterned layer 230a is formed between the insulating layer 210 and the pad metal layer 220 so that the pad metal layer 220 has an uneven surface. The patterned layer 230a can be an amorphous layer or a polysilicon layer, for example.

Please refer to FIG. 3B, in another embodiment, the at least a patterned layer comprises a first patterned layers 230 and a second patterned layer 230a. The first patterned layer 230 is disposed between the insulating layer 210 and the substrate 260, and the second patterned layer 230a is disposed between the insulating layer 210 and the pad metal layer 220. The first patterned layer 230 between the insulating layer 210 and the substrate 260 is a metal layer, for example. The second patterned layer 230a between the insulating layer 210 and the pad metal layer 220 is an amorphous layer or a polysilicon layer, for example. The two patterned layer 230, 230a can increase the surface roughness of each layer of the bonding pad so as to improve the adhesion between layers of the bonding pad.

In addition, as shown in FIG. 3B and FIG. 3C, the pattern of the first patterned layer 230 between the insulating layer 210 and the substrate 260 and the pattern of the second patterned layer 230a between the insulating layer 210 and the pad metal layer 220 are aligned to each other (as shown in FIG. 3B) or not aligned to each other (as shown in FIG. 3C). If the patterns of the first patterned layer 230 and the pattern of the second patterned layer 230a are not aligned to each other (as shown in FIG. 3C), the surface roughness of each layer in the bonding pad is higher, and thus the adhesion between layers of the bonding pad is better.

In particular, the two patterned layers 230, 230a shown in FIG. 2A and FIG. 3A˜3C respectively have at least a pattern selected from a circular pattern, a square pattern, a polygon pattern and a combination thereof. The pattern of the first patterned layer 230 between the insulating layer 210 and the substrate 260 can be the same to or different from that of the second patterned layer 230a between the insulating layer 210 and the pad metal layer 220.

Accordingly, the surface roughness of each layer of the bonding pad can be increased through forming the patterned layer so as to improve the adhesion between layers of the bonding pad. Especially, the adhesion between the pad metal layer 220 and the insulating layer 210 can be improved. Hence, the pad metal layer 220 does not peel off the insulating layer 210 when repairing driving chip.

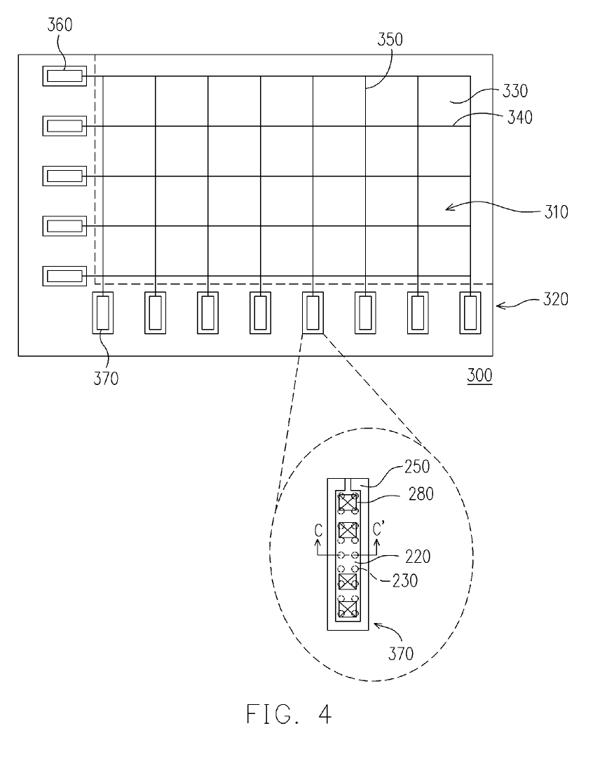

FIG. 4 is a top view showing a display panel according to an embodiment of the present invention. As shown in FIG. 4, the display panel 300 has a display region 310 and a non-display region 320. The display panel 300 comprises a plurality of pixel units 330, a plurality of scan lines 340, a plurality of data lines 350, a plurality of scan line pads 360 and a plurality of data line pads 370. The pixel units 330 are disposed in the display region 310. The data lines 350 and the scan lines 340 are disposed in the display region 310 and electrically connected to the pixel units 330. The scan line pads 360 are disposed in the non-display region 320 and electrically connected to the scan lines 340. The data line pads 370 are disposed in the non-display region 320 and electrically connected to the data lines 350.

It should be noted that each data line pad 370 can be designed as the bonding pad 200 shown in FIG. 2. In other words, the cross-section view along the B-B′ line of the data line pad 370 in FIG. 4 can be as same as the structure of FIG. 2A, FIG. 3A, FIG. 3B or FIG. 3C. The patterns, the pattern arrangement of the patterned layers 230, 230a are the same or similar to the above mentioned and are omitted. The display panel having the data line pads 370 therein can be a liquid crystal display panel, organic electroluminescent display panel or plasma display panel. If the bonding pads 200 are applied to the display panel 300, the display panel process yield can be improved.

For the forgoing, the bonding pad and the display panel of the present invention have advantages as follows:

The binding pad has at least a patterned layer that is disposed between the insulating layer and the substrate or/and between the insulating layer and the pad metal layer. Thus, the adhesion between the pad metal layer and the insulating layer can be improved.

Because the adhesion between the pad metal layer and the insulating layer is increased, the pad metal layer does not peel off the insulating layer.

If the bonding pad of the present invention is applied to a display panel, the display panel process yield can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bonding pad, comprising:
an insulating layer, disposed on a substrate;
a pad metal layer, disposed over the insulating layer;
at least a patterned layer, disposed in at least one of the positions of between the insulating layer and the substrate and between the insulating layer and the pad metal layer so that the insulating layer or the pad metal layer has an uneven surface;
a passivation layer, disposed over the pad metal layer; and
a conductive layer, disposed over the passivation layer, and the conductive layer is electrically connected to the pad metal layer.

2. The bonding pad according to claim 1, wherein the at least a patterned layer is a metal layer and is disposed between the insulating layer and the substrate.

3. The bonding pad according to claim 1, wherein the at least a patterned layer is an amorphous layer or a polysilicon layer and is disposed between the insulating layer and the pad metal layer.

4. The bonding pad according to claim 1, wherein the at least a patterned layer comprises a first patterned layer disposed between the insulating layer and the substrate and a second patterned layer between the insulating layer and the pad metal layer, and the first patterned layer between the insulating layer and the substrate is a metal layer and the second patterned layer between the insulating layer and the pad metal layer is an amorphous layer or a polysilicon layer.

5. The bonding pad according to claim 4, wherein the first patterned layer between the insulating layer and the substrate has a pattern the same to or different from that of the second patterned layer between the insulating layer and the pad metal layer.

6. The bonding pad according to claim 4, wherein the pattern of the first patterned layer between the insulating layer and the substrate and the pattern of the second patterned layer between the insulating layer and the pad metal layer are aligned or not aligned to each other.

7. The bonding pad according to claim 1, wherein the patterned layer has at least a pattern selected from a circular pattern, a square pattern, a polygon pattern and a combination thereof.

8. The bonding pad according to claim 1, wherein the conductive layer comprises a metal oxide.

9. A display panel having a display region and a non-display region, comprising:
a plurality of pixel units, disposed in the display region;
a plurality of data lines and a plurality of scan lines, disposed in the display region and electrically connected to the pixel units;
a plurality of scan line pads, disposed in the non-display region and electrically connected to the scan lines;
a plurality of data line pads, disposed in the non-display region and electrically connected to the data lines, wherein each of the data line pad comprises:
an insulating layer, disposed on a substrate;
a pad metal layer, disposed over the insulating layer;
at least a patterned layer, disposed in at least one of the positions of between the insulating layer and the substrate and between the insulating layer and the pad metal layer so that the insulating layer or the pad metal layer has an uneven surface;
a passivation layer, disposed over the pad metal layer; and
a conductive layer, disposed over the passivation layer, and the conductive layer is electrically connected to the pad metal layer.

10. The display panel according to claim 9, wherein the at least a patterned layer is a metal layer and is disposed between the insulating layer and the substrate.

11. The display panel according to claim 9, wherein the at least a patterned layer is an amorphous layer or a polysilicon layer and is disposed between the insulating layer and the pad metal layer.

12. The display panel according to claim 9, wherein the at least a patterned layer comprises a first patterned layer disposed between the insulating layer and the substrate and a second patterned layer between the insulating layer and the pad metal layer, and the first patterned layer between the insulating layer and the substrate is a metal layer and the second patterned layer between the insulating layer and the pad metal layer is an amorphous layer or a polysilicon layer.

13. The display panel according to claim 12, wherein the first patterned layer between the insulating layer and the substrate has a pattern the same to or different from that of the second patterned layer between the insulating layer and the pad metal layer.

14. The display panel according to claim 12, wherein the pattern of the first patterned layer between the insulating layer and the substrate and the pattern of the second patterned layer between the insulating layer and the pad metal layer are aligned or not aligned to each other.

15. The display panel according to claim 9, wherein the patterned layer has at least a pattern selected from a circular pattern, a square pattern, a polygon pattern and a combination thereof.

16. The display panel according to claim 9, wherein the conductive layer comprises a metal oxide.
